(19) United States
(12) Patent Application Publication
(10) Pub. No.: US 2021/0215764 A1
(43) Pub. Date: Jul. 15, 2021

(54) A METHOD AND A SYSTEM FOR DISCHARGING A BATTERY IN A FULL LIFE CYCLE

(71) Applicant: CHANGXING TAIHU ELECTRIC CORPORATION, Huzhou (CN)

(72) Inventors: Jianbin WU, Huzhou (CN); Chi CHEN, Huzhou (CN)

(21) Appl. No.: 16/852,368

(22) Filed: Apr. 17, 2020

(30) Foreign Application Priority Data
Jan. 9, 2020 (CN) 2020100199063

(51) Int. Cl. G01R 31/36; G01R 31/396; G01R 31/392; G01R 31/374; G01R 31/3842

(52) U.S. Cl. CPC G01R 31/3648; G01R 31/396; H01M 10/441; G01R 31/374; G01R 31/3842; G01R 31/392

(57) ABSTRACT

The method for discharging the cell includes: pulsively discharging a load, where a discharge pulse forms, through current filtering, a current waveform required by the load; a pulse amplitude of the discharge pulse is a discharge current of a cell, a pulse width of the discharge pulse is not greater than a recovery time t_{c}, and a pulse interval of the discharge pulse is not less than a relaxation time tᵣ; and the recovery time is a largest continuous discharge time of the cell, and distortion of an electrode structure caused within the time can be eliminated in the subsequent relaxation time. The present invention is applicable to intelligent control of discharging of various electrochemical batteries, so that a load (a working condition), discharging, and battery management are fully matched and optimized, each cell works in a healthy running area, and a battery life is prolonged.

### TECHNICAL FIELD

The present invention relates to the field of battery management technologies, and in particular, to a method for discharging a cell, and a method and system for discharging a battery in a full life cycle.

### BACKGROUND

An electrochemical energy storage technology is currently a mainstream technology for distributed energy storage, and is a guarantee for use of renewable energy sources in a large proportion. Electrochemical energy storage has a short construction cycle, a short cycle of return on investment, and a low environmental requirement, and can be distributed for construction, and is suitable for storage of distributed renewable energy sources. A battery is a core of electrochemical energy storage and a core component of an electric vehicle. A safe, economical, environmentally friendly, and reproducible battery system is a core of electrochemical energy storage. Because a battery product has a distinct life characteristic, to healthily and safely use the battery system requires life-cycle control and management on the battery system. A discharge technology is one of keys to healthy and safe use of the battery system.

Improper discharge methods, especially frequent over-discharges, greatly shorten a battery life and even cause serious safety hazards. Some of spontaneous combustion of lithium-battery electric vehicles and deflagration accidents in energy storage power stations that are frequently occurred recently are directly related to long-term over-discharges of cells of batteries. For lead-acid batteries, frequent over-discharges may accelerate battery sulfation, thereby severely shortening a battery life. A large battery system is generally formed by connecting a plurality of cells in parallel. Although consistency among new cells can be guaranteed when they are grouped, as a battery ages, the consistency deteriorates. In this way, some cells are inevitably over-discharged in a discharge process, thereby causing the battery system to fail. For this reason, a discharge method that is used to effectively delay or control a failure of the battery system is of great significance.

Complexity of discharge control comes from uncontrollability of a discharge load during discharge control. With widespread use of an electric system, discharge behavior depends to a large extent on a working condition and the load of the electric system, such as use of an electric vehicle, and frequency and peak modulation of a power grid system. The load is determined by an external environment and the working condition. During use of the electric system and the energy storage system, how to ensure a healthy discharge of each cell without affecting completion of a work task is a problem that an intelligent discharge control system must face.

The patent CN201310317219.X for the invention discloses a method for estimating a capacity of a lithium ion battery and predicting a remaining cycle life. The method includes: using, as test data, a collected quantity x of charge and discharge cycles of a battery, a discharge voltage and a battery capacity in each charge and discharge cycle, and a/n of data z of a remaining capacity of the battery after each charge and discharge, and remaining (n−a)/n of the data; expanding the training data by using a segmented cubic Hermite interpolation method; performing modeling by using training data of different interpolation points obtained after the expansion; performing extrapolation prediction by using GPR models with different parameters; and predicting a remaining capacity of the battery obtained after N charge and discharge cycles of the lithium battery, to obtain the remaining capacity of the battery after the N charge and discharge cycles. Although a problem that capacity estimation and prediction of a remaining life of the lithium battery cannot be achieved can be resolved by using the method, this method is based on determining of a post-event state of the battery. However, in some load cases, an over-discharge has occurred, and a long-term over-discharge may cause a state of health of the battery to decline.

### SUMMARY

For the problem existing in the prior art, the present invention provides a method for discharging a cell, and a method and system for discharging a battery in a full life cycle. Life-cycle management is performed on the battery, to grasp an operation and health status of each cell in the battery. Inconsistent pressure generated by a battery discharge on each cell is predicted based on a possible load and working condition. A state of charge (SOC) and a state of power (SOP) of each cell are balanced in advance, to ensure that no unrecoverable over-discharge occurs on the cell under a complex load and working condition, so that battery use safety can be greatly improved and a battery life can be prolonged.

The present invention is implemented based on the following technical solutions:

A method for discharging a cell is provided, including:
pulsively discharging a load, where a discharge pulse forms, through current filtering, a current waveform required by the load, where
a pulse amplitude of the discharge pulse is a discharge current of the cell, a pulse width of the discharge pulse is not greater than a recovery time t_{c}, and a pulse interval of the discharge pulse is not less than a relaxation time tᵣ;
the recovery time is a largest continuous discharge time of the cell, and distortion of an electrode structure caused within the time can be eliminated in the subsequent relaxation time; and
the relaxation time is a time required for recovering a distorted electrode structure to an original state.

The present invention provides a pulsive discharge method. There is an interval after a single pulse is ended, so that accumulation of distortion within a pulse period can be reduced or eliminated. In this way, an aging degree can no doubt be reduced.

Preferably, the recovery time t_{c} varies with the discharge current of the cell, temperature, a state of health SOH of a battery, a state of charge SOC, and a depth of discharge DOD of the battery.

Preferably, the recovery time t_{c} is in inverse proportion to the discharge current of the cell, and the recovery time t_{c} is in inverse proportion to a depth of discharge DOD of a battery.

Preferably, the relaxation time tᵣ varies with the discharge current of the cell, temperature, a state of health SOH of a battery, a state of charge SOC, and a depth of discharge DOD of the battery.

Preferably, a minimum value of the relaxation time tᵣ is in direct proportion to the discharge current of the cell.

Preferably, the method further includes: performing a discharge process until the load is fully charged or the cell is discharged to a cut-off state.

A method for discharging a battery in a full life cycle is provided, including:
monitoring real-time data of a discharged battery and real-time data of a load based on a discharge pulse at a current moment;
calculating a discharge pulse at a next moment based on the real-time data of the load, the real-time data of the battery, and change information of a recovery time t_{c} and a relaxation time tᵣ;
forming, by the discharge pulse by controlling current filtering, a current waveform at the next moment required by the load; and
performing discharging by using the calculated discharge pulse, charging the load by using the current waveform obtained after calculation, and performing a discharge process until the load is fully charged or the battery is discharged to a cut-off state, where
the real-time data of the battery includes voltage, current, and temperature data of the battery, and the real-time data of the load includes voltage, current, and temperature data of the load;
the recovery time is a largest continuous discharge time of the battery, and distortion of an electrode structure caused within the time can be eliminated in the subsequent relaxation time; and the recovery time t_{c} varies with a discharge current of a cell, temperature, a state of health SOH of the battery, a state of charge SOC, and a depth of discharge DOD of the battery;
the relaxation time tᵣ is a time required for recovering a distorted electrode structure to an original state, and the relaxation time tᵣ varies with the discharge current of the cell, the temperature, the state of health SOH of the battery, the state of charge SOC, and the depth of discharge DOD of the battery; and
the discharge pulse includes the discharge current of the cell, the recovery time t_{c}, and the relaxation time tᵣ.

In the present invention, life-cycle management is performed on the battery, to grasp an operation and health status of each cell in the battery. Inconsistent pressure generated by a battery discharge on each cell is predicted based on a possible load and working condition. A state of charge (SOC) and a state of power (SOP) of each cell are balanced in advance, to ensure that no unrecoverable over-discharge occurs on the cell under a complex load and working condition.

Preferably, the step of calculating a discharge pulse at a next moment based on the real-time data of the load, the real-time data of the battery, and change information of a recovery time t_{c} and a relaxation time tᵣ includes:
determining a predicted load curve based on the real-time data of the load;
determining a discharge pulse of each cell at the next moment based on the real-time data of the battery, in comparison with a curve of the recovery time t_{c} and the relaxation time tᵣ of each cell varying with the discharge current of the cell, the temperature, the state of health SOH of the battery, the state of charge SOC, and the depth of discharge DOD of the battery, and with reference to the predicted load curve; and
constituting a discharge pulse of the battery at the next moment by using a minimum value of discharge currents, a minimum value of the recovery time, and a maximum value of the relaxation time of all cells.

Preferably, when the battery includes a serially connected cell, the step of calculating a discharge pulse at a next moment based on the real-time data of the load, the real-time data of the battery, and change information of a recovery time t_{c} and a relaxation time tᵣ further includes:
before the discharge pulse of each cell at the next moment is determined, if at least one of a plurality of cells is close to a discharge cut-off state, charging the cell close to a discharge cut-off state by using another cell; and
then determining the discharge pulse of each cell at the next moment based on the real-time data of the battery, in comparison with the curve of the recovery time t_{c} and the relaxation time tᵣ of each cell varying with the discharge current of the cell, the temperature, the state of health SOH of the battery, the state of charge SOC, and the depth of discharge DOD of the battery, and with reference to the predicted load curve.

Preferably, the step of forming, by the discharge pulse by controlling current filtering, a current waveform at the next moment required by the load includes:
performing filtering calculation, performing filtering processing when a load curve obtained through calculation is consistent with the predicted load curve, and filtering the discharge pulse to form the current waveform.

Preferably, the method for discharging the battery in a full life cycle is applicable to a battery formed by serially connecting a plurality of cells, or a battery formed by connecting a plurality of cells in parallel, or a battery formed by connecting a plurality of cells serially and in parallel.

Preferably, the method further includes: correcting a curve of each cell in real time based on the real-time data of the battery, the state of health SOH of the battery, the state of charge SOC, and the depth of discharge DOD of the battery.

Preferably, the method is applicable to a discharge of a chemical battery.

A system for discharging a battery in a full life cycle is provided, including a battery module, a detection and protection module, a load, a load detection module, a current filtering module, a database, and a calculation control module; the database stores change information of a recovery time t_{c} and a relaxation time tᵣ of the battery; the detection and protection module is configured to detect the battery module in real time, to obtain real-time data of the battery; the load detection module is configured to detect the load in real time, to obtain real-time data of the load; the calculation control module calculates a discharge pulse at a next moment based on the real-time data of the load, the real-time data of the battery, and the change information of the recovery time t_{c} and the relaxation time tᵣ of the battery; the battery module performs discharging based on a control signal of the calculation control module, and forms, by the discharge pulse by using the current filtering module, a current waveform required by the load, until the load is fully charged or a cell is discharged to a cut-off state;
the real-time data of the battery includes voltage, current, and temperature data of the battery, and the real-time data of the load includes voltage, current, and temperature data of the load;
the recovery time t_{c} is a largest continuous discharge time of the battery, and distortion of an electrode structure caused within the time can be eliminated in the subsequent relaxation time; and the recovery time t_{c} varies with a discharge current of the cell, temperature, a state of health SOH of the battery, a state of charge SOC, and a depth of discharge DOD of the battery;
the relaxation time tᵣ is a time required for recovering a distorted electrode structure to an original state, and the relaxation time tᵣ varies with the discharge current of the cell, the temperature, the state of health SOH of the battery, the state of charge SOC, and the depth of discharge DOD of the battery; and
the discharge pulse includes the discharge current of the cell, the recovery time t_{c}, and the relaxation time tᵣ.

Preferably, the calculation control module includes:
a load curve determining unit, configured to determine a predicted load curve based on the real-time data of the load;
a cell discharge pulse calculation unit, configured to determine a discharge pulse of each cell at a next moment based on the real-time data of the battery, in comparison with a curve of the recovery time t_{c} and the relaxation time tᵣ of each cell varying with the discharge current of the cell, the temperature, the state of health SOH of the battery, the state of charge SOC, and the depth of discharge DOD of the battery, and with reference to the predicted load curve; and
a battery discharge pulse calculation unit, configured to constitute a discharge pulse of the battery at a next moment by using a minimum value of discharge currents, a minimum value of the recovery time, and a maximum value of the relaxation time of all cells.

Preferably, the calculation control module further includes: a filtering calculation unit, configured to perform filtering calculation on the discharge pulse of the battery; when a load curve obtained through calculation is consistent with the predicted load curve, the calculation control module sends a control instruction including the discharge pulse of the battery to the battery module; otherwise, the load curve determining unit, the cell discharge pulse calculation unit, and the battery discharge pulse calculation unit calculate the discharge pulse of the battery again.

Preferably, the system further includes a battery energy management module and a switch module that are disposed between the battery module and the current filtering module; the calculation control module further includes a charge control unit, configured to: when the battery energy management module detects that at least one of a plurality of cells is close to a discharge cut-off state, control the switch module to cut off a discharge path and control another cell to charge the cell close to a discharge cut-off state; and after the charging is completed, then control the switch module to turn on the discharge path, and trigger the load curve determining unit, the cell discharge pulse calculation unit, and the battery discharge pulse calculation unit to work.

The present invention has the following beneficial effects:

The present invention provides a method for discharging a cell, and a method and system for discharging a battery in a full life cycle, and is applicable to intelligent control of discharging of various electrochemical batteries, so that a load (a working condition), discharging, and battery management are fully matched and optimized, each cell works in a healthy running area, and a battery life is prolonged.

### BRIEF DESCRIPTION OF THE DRAWINGS

FIG. 1a is a block diagram of a discharge structure of a battery with a single cell;

FIG. 1b is a discharge curve diagram (a discharge current I−a discharge time t) shown based on the structure in FIG. 1a;

FIG. 2a is a block diagram of a discharge structure of a battery with a plurality of serially connected cells;

FIG. 2b is a discharge curve diagram (a discharge current I−a discharge time t) shown based on the structure in FIG. 2a;

FIG. 3 is a curve diagram of a trend in which a battery cycle life varies with a discharge current and a depth of discharge;

FIG. 4 is a schematic diagram of a discharge pulse of a battery;

FIG. 5a is a schematic diagram of a change of a recovery time t_{c}−a depth of discharge DOD;

FIG. 5b is a curve diagram of a recovery time varying with a depth of discharge DOD, where a change in a discharge current also affects a change in the curve;

FIG. 6 is a flow block diagram of a method for discharging a battery in a full life cycle according to the present invention;

FIG. 7a shows a structure of a battery formed by a plurality of cells that are serially connected successively;

FIG. 7b shows a structure of a battery formed by a plurality of cells that are connected in parallel to each other;

FIG. 7c is a schematic diagram of a battery formed by a plurality of cells that are connected serially and in parallel, where the battery in the figure is formed by successively and serially connecting a plurality of groups of cells connected in parallel;

FIG. 7d is a schematic diagram of a battery formed by a plurality of cells that are connected serially and in parallel, where the battery in the figure is formed by connecting, in parallel to each other, a plurality of groups of serially connected cells;

FIG. 8 is a schematic diagram of a system for discharging a battery with a single cell in a full life cycle; and

FIG. 9 is a schematic diagram of a system for discharging a battery with a plurality of cells in a full life cycle.

### DETAILED DESCRIPTION

The following are specific embodiments of the present invention and the technical solutions of the present invention are further described with reference to the accompanying drawings. However, the present invention is not limited to these embodiments.

At present, battery discharge management focuses on a state of charge (SOC), a state of health (SOH) of a battery, internal resistance, a state of power (SOP), and the like, and is rarely linked to a load of the battery. Due to a non-linear relationship of the SOC, the SOP, the SOH, and the internal resistance to a load current/voltage height, it is relatively difficult to predict impact of the load on a battery state before a complex load appears. In this way, the battery can be protected only based on determining of a post-event state. In some load cases, determining is performed after an over-discharge occurs. If recovery is not performed in time, damage may be caused to the battery, and a long-term over-discharge may cause battery health to decline. Because the battery has a distinct life characteristic, a characteristic parameter of the battery changes as the battery ages. Therefore, in a battery discharge control method, adaptive discharge management should be performed based on a life characteristic of the battery, especially when life-cycle management is performed on the battery.

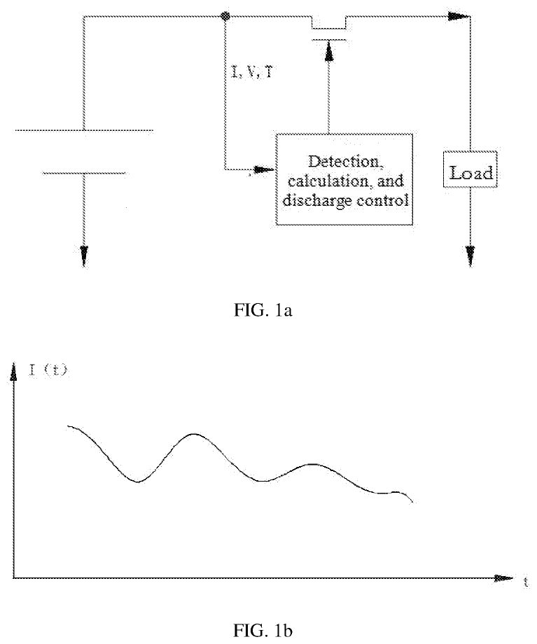

FIG. 1a and FIG. 1b are diagrams of a discharge of a battery with a single cell. A battery with a single cell is discharged to supply discharged electricity to a load. A current I_{load} required by the load within a charge time t_{charge} needs to be supplied through a battery discharge, and a load-side current needs to be smoothed. When the battery is pulsively discharged, filtering processing is required. A loss of some charges exists during the filtering processing. Therefore, electricity discharged by the battery is at least I_{load}*t_{charge}/t_{discharge}. It can be seen that, regardless of a lithium battery, a lead-acid battery, or another electrochemical battery, a cut-off voltage at which the cell of the battery is fully discharged is related to a load current for the discharge.

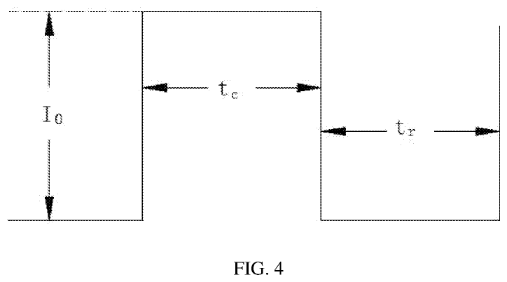

FIG. 3 describes a trend in which a cycle life varies with a discharge current and a depth of discharge. A cycle life of a battery is in inverse proportion to a depth of discharge DOD of the battery. A deeper discharge leads to a shorter cycle life. In addition, the cycle life of the battery is in inverse proportion to a discharge current (a discharge rate). A larger discharge current leads to a shorter cycle life. A cycle life is a quantity of times the battery is used repeatedly and can still maintain 80% of a capacity. A decline in the battery capacity and aging is a gradual decline accumulation process. From a microstructure perspective, the accumulation is accumulation of distortion of an electrode structure. Aging of the battery is caused by the distortion of the electrode structure in most cases in a charge and discharge process. The discharge process is also a key to aging of the battery. A lithium battery is used as an example, a discharge process is a process in which a lithium ion of a negative electrode is deintercalated and a lithium ion of a positive electrode is intercalated. Within this period, distortion of structures of the positive and negative electrodes, precipitation of lithium metal, a dendritic growth, a change in an SEI film, and the like cause aging. Experience indicates that a larger discharge current and longer discharge duration accelerate aging of the battery. If irreversible distortion during this discharge can be eliminated in each discharge process, the distortion is not accumulated. During actual application, due to complexity of a discharge case, recovery cannot be performed if distortion is eliminated after the battery is fully discharged. However, a pulse discharge within a relatively short time may reduce distortion in a single-pulse discharge period, and the distortion can be recovered in a non-discharge state. Therefore, pausing needs to be performed for recovery in the discharge process.

It can be seen that a deep discharge or a long-term large-current discharge accelerates aging of the battery, because irreversible distortion of an electrode structure is quickly accumulated. If the battery is pulsively discharged, and a width of each discharge pulse is controlled within a time tₓ, distortion of the electrode structure caused by the pulse discharge can be recovered after the pulse ends. A maximum value of tₓ is defined as a maximum recoverable time t_{c}. Within an interval after each pulse, it is ensured that irreversible distortion of the electrode structure can be eliminated. A minimum value tᵣ of the interval is a relaxation time for recovering distortion of the electrode structure. Electrode distortion of the battery generated within the pulse discharge width t_{c} can be eliminated within an immediately following relaxation time. Aging of the battery caused through the discharge can be greatly pulsively reduced.

Based on this, as a general description, a pulse amplitude I₀ (as shown in FIG. 4) of the discharge pulse is the discharge current of the battery, the pulse width of the discharge pulse is not greater than the recovery time t_{c}, and the pulse interval of the discharge pulse is not less than the relaxation time tᵣ. The recovery time is a largest continuous discharge time of the battery, and distortion of the electrode structure caused within the time can be eliminated in the subsequent relaxation time. The relaxation time is a time required for recovering a distorted electrode structure to an original state.

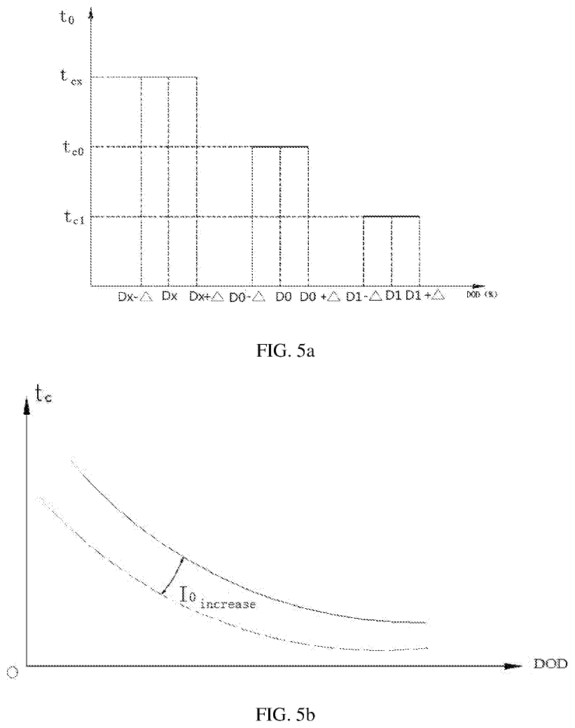

The recovery time t_{c} varies with the discharge current of the battery, temperature, a state of health SOH of the battery, a state of charge SOC, and a depth of discharge DOD of the battery. As shown in FIG. 5a, recovery time t_{c} vary at different depths of discharge. For example, when a depth Dₓ of discharge is relatively small, a recovery time t_{cx} is relatively large, and a pulse starts at DOD=(Dₓ−delta) and ends at (Dₓ+delta). When a depth D₁ of discharge is relatively large, a recovery time t_{c1} is relatively small, and the discharge pulse starts from DOD =(D₁−delta) and ends at (D₁+delta). Generally, as shown in FIG. 5b, the recovery time t_{c} is in inverse proportion to the discharge current of the battery, and the recovery time t_{c} is in inverse proportion to the depth of discharge DOD of the battery.

The relaxation time tᵣ varies with the discharge current of a battery, temperature, a state of health SOH of the battery, a state of charge SOC, and a depth of discharge DOD of the battery. A minimum value of the relaxation time tᵣ is in direct proportion to the pulse current amplitude.

In a same discharge cycle, at a cut-off voltage (DOD=100%), the recovery time t_{c} is the smallest and the relaxation time tᵣ is the largest. Theoretically, a smaller discharge pulse amplitude, a smaller recovery time t_{c}, and a larger relaxation time tᵣ lead to less damage caused by a discharge to the battery. However, due to a requirement of the load, both a t_{c}/tᵣ ratio and the pulse amplitude in the discharge pulse need be appropriate to ensure that a current waveform required by the load can be generated after the pulse passes through a filter.

From a safety point of view, a pulse amplitude of the discharge current should not be excessively large; otherwise, other damage to the battery is caused due to overheating. The maximum amplitude of the discharge pulse depends on electrochemical performance of various batteries, heat dissipation of a battery system, a battery production process, and a state of charge and a state of health of the battery. A lithium-ion battery is used as an example, and a long-term high-current discharge easily leads to the precipitation of lithium from an anode, thereby causing thermal runaway under a condition. Generally, a maximum discharge current of a new cell under a same condition is larger, and is generally provided by a manufacturer. As the battery continuously ages, the maximum pulse amplitude decreases. In order to ensure that a current waveform obtained after filtering meets a requirement of the load, when a current pulse amplitude is limited, the pulse duty factor (a tₓ/tᵣ value) is increased to match a filtering current and the load.

Based on the above characteristics, the present invention provides a method for discharging a cell, including: pulsively discharging a load, where a discharge pulse forms, through current filtering, a current waveform required by the load. A pulse amplitude of the discharge pulse is a discharge current of the cell, a pulse width of the discharge pulse is not greater than a recovery time t_{c}, and a pulse interval of the discharge pulse is not less than a relaxation time tᵣ. A discharge process is performed until the load is fully charged or the cell is discharged to a cut-off state.

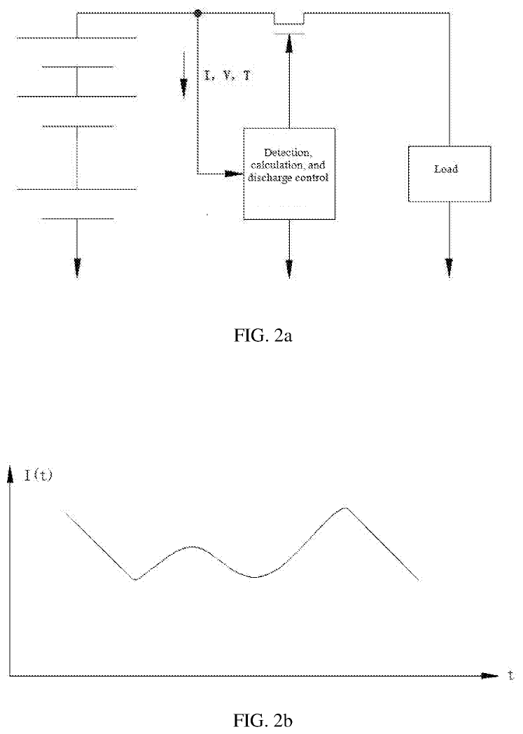

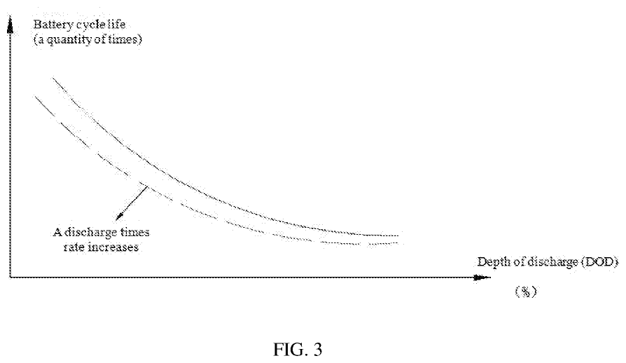

FIG. 2a and FIG. 2b are diagrams of a discharge of a battery with a plurality of cells. In a system in which a plurality of cells are serially connected, because consistency among cells is different and aging degrees of the cells are different, a parameter of each cell evolves as the battery ages. Therefore, for a relatively weak cell, an over-discharge inevitably occurs when the system is discharged. A current battery control system has no management system that adjusts over-discharge behavior of the battery in real time. Furthermore, due to consistency among the cells and complexity of the load, it is very important for the discharge system to predict a discharge capability of each cell. Pre-balancing is performed based on load prediction and the discharge capability of each cell, so as to ensure that support of the battery system for the load is the most durable while each cell of the battery is not over-discharged. At present, the battery control system is relatively poor in preventing an over-discharge of the battery, and cannot release electric energy stored in each cell to a greatest extent. In the long run, a weak cell is getting weaker, and a capacity of the battery system rapidly declines, thereby accelerating aging of the battery system.

As information about the battery system having life characteristics, a discharge curve and an over-discharge state need to be determined in real time when life-cycle management is performed, to ensure healthy operation of the battery system. To this end, the present invention provides a method and system for discharging a battery in a full life cycle.

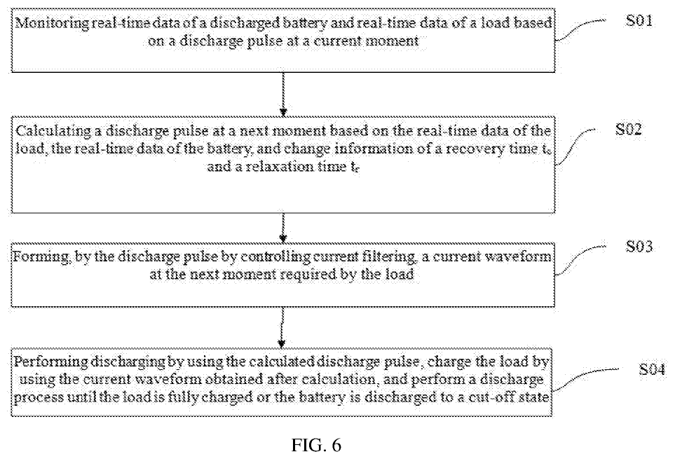

As shown in FIG. 6, a method for discharging a battery in a full life cycle includes the following steps:

Step S01. Monitoring real-time data of a discharged battery and real-time data of a load based on a discharge pulse at a current moment.

Step S02. Calculating a discharge pulse at a next moment based on the real-time data of the load, the real-time data of the battery, and change information of a recovery time t_{c} and a relaxation time tᵣ.

Step S03. Forming, by the discharge pulse by controlling current filtering, a current waveform at the next moment required by the load.

Step S04. Performing discharging by using the calculated discharge pulse, charge the load by using the current waveform obtained after calculation, and perform a discharge process until the load is fully charged or the battery is discharged to a cut-off state.

The real-time data of the battery includes voltage, current, and temperature data of the battery, and the real-time data of the load includes voltage, current, and temperature data of the load.

The recovery time is a largest continuous discharge time of the battery, and distortion of an electrode structure caused within the time can be eliminated in the subsequent relaxation time. The recovery time t_{c} varies with a discharge current of a cell, temperature, a state of health SOH of the battery, a state of charge SOC, and a depth of discharge DOD of the battery.

The relaxation time tᵣ is a time required for recovering a distorted electrode structure to an original state, and the relaxation time tᵣ varies with the discharge current of the cell, the temperature, the state of health SOH of the battery, the state of charge SOC, and the depth of discharge DOD of the battery.

The discharge pulse includes the discharge current of the cell, the recovery time t_{c}, and the relaxation time tᵣ.

In step S02, because the recovery time t_{c} and the relaxation time tᵣ vary with the discharge current of the cell, the temperature, the state of health SOH of the battery, the state of charge SOC, and the depth of discharge DOD of the battery, the change information is recorded by using a curve of the recovery time t_{c}—the depth of discharge DOD of the battery (as shown in FIG. 5b) and a curve of the relaxation time tᵣ—the depth of discharge DOD of the battery. A minimum value of the relaxation time tᵣ is in direct proportion to a pulse current amplitude. The foregoing curve is initially formed based on initial data provided by a battery manufacturer, and is subsequently corrected in real time based on historical data during use, such as temperature, an SOH, an SOC, a depth of discharge, a discharge current, and voltage data. For this reason, when the real-time data of the battery is compared with the change information, a corresponding appropriate discharge pulse is obtained with reference to a curve for a next discharge.

This method is applicable to various types of electrochemical batteries, such as a lithium battery, a lead-acid battery, and a super capacitor. The battery used in the specification may be a battery with a single cell or a battery formed by a plurality of cells.

When discharge management is performed on the battery with a single cell, the real-time data of the discharged battery and the real-time data of the load are monitored based on the discharge pulse at the current moment. The state of charge SOC and the state of health SOH of the battery are determined based on the monitored real-time data of the battery including temperature, current, and voltage data. A load curve is predicted based on the monitored real-time data of the load including voltage, current, and temperature data of the load. Then the discharge pulse at the next moment is calculated based on the real-time data of the load, the real-time data of the battery, and change information of the recovery time t_{c} and the relaxation time tᵣ. A discharge pulse of each cell at a next moment is determined based on the real-time data of the battery, in comparison with a curve of the recovery time t_{c} and the relaxation time tᵣ of each cell varying with the discharge current of the cell, the temperature, the state of health SOH of the battery, the state of charge SOC, and the depth of discharge DOD of the battery, and with reference to the predicted load curve.

When discharging management is performed on the battery with a plurality of cells, there are various forms of a structure of the battery formed by the plurality of cells, such as a battery formed by a plurality of cells that are serially connected successively, a battery formed by a plurality of cells that are connected in parallel to each other, a battery formed by successively and serially connecting a plurality of groups of cells connected in parallel, a battery formed by connecting, in parallel to each other, a plurality of groups of serially connected cells. The battery is not limited to the foregoing structure, and may be of any battery structure conforming to a use requirement. Based on management performed on the battery with a plurality of cells, the step of calculating the discharge pulse is further detailed as follows:
(a) determining the predicted load curve based on the real-time data of the load;
(b) determining the discharge pulse of each cell at the next moment based on the real-time data of the battery, in comparison with the curve of the recovery time t_{c} and the relaxation time tᵣ of each cell varying with the discharge current of the cell, the temperature, the state of health SOH of the battery, the state of charge SOC, and the depth of discharge DOD of the battery, and with reference to the predicted load curve; and
(c) constituting a discharge pulse of the battery at the next moment by using a minimum value of discharge currents, a minimum value of the recovery time, and a maximum value of the relaxation time of all cells.

Then a current waveform at the next moment required by the load is formed by the discharge pulse by controlling current filtering. Specifically, filtering calculation is performed, filtering processing is performed when a load curve obtained through calculation is consistent with the predicted load curve, and the discharge pulse is filtered to form the current waveform. If there is an error between the load curve obtained through calculation and the predicted load curve, the discharge pulse needs to be calculated again.

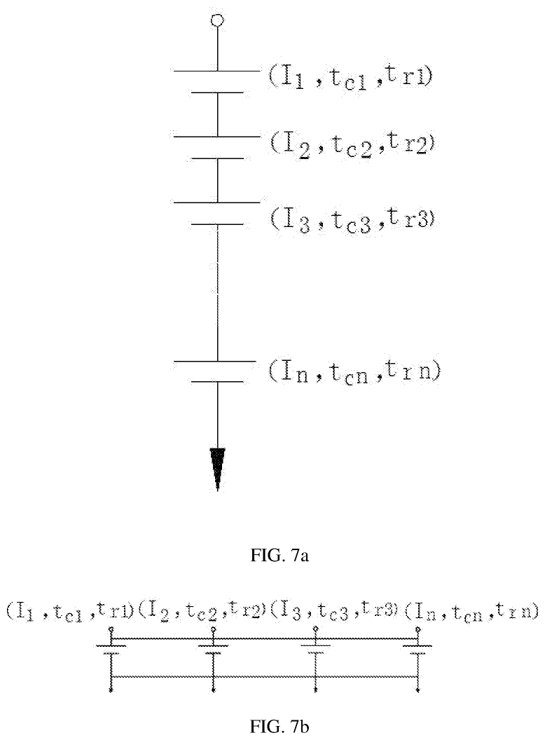

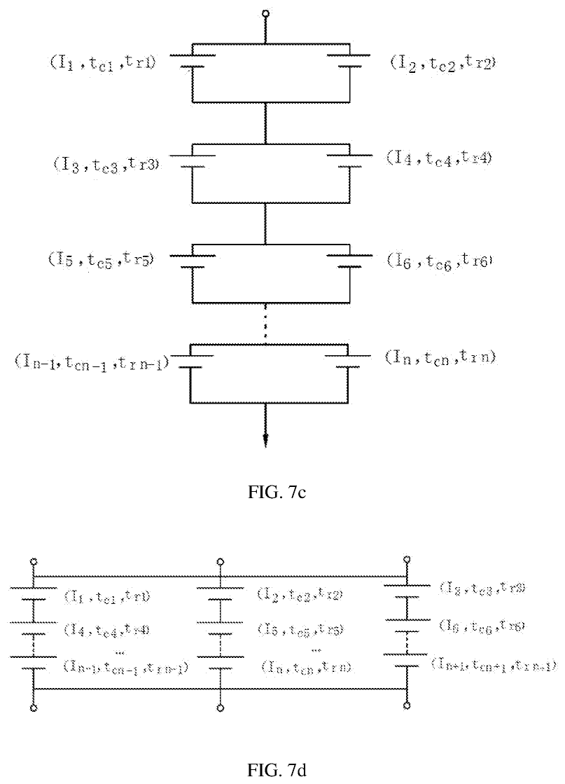

The battery formed by the plurality of cells that are serially connected successively shown in FIG. 7a is used as an example. The real-time data of the battery includes temperature 1, a discharge current 1, a discharge voltage 1, a depth 1 of discharge, an SOC 1, and an SOH 1 of a cell 1; temperature 2, a discharge current 2, a discharge voltage 2, a depth of discharge 2, an SOC 2, and an SOH 2 of a cell 2; temperature 3, a discharge current 3, a discharge voltage 3, a depth 3 of discharge, an SOC 3, and an SOH 3 of a cell 3 . . . ; temperature n, a discharge current n, a discharge voltage n, a depth n of discharge, an SOC n, and an SOH n of a cell n. Each cell includes parameters of a discharge current I, a recovery time t_{c}, and a relaxation time tᵣ (referring to FIG. 7a). First, by predicting the load curve, an amplitude and a width of the discharge current pulse are measured, and then the pulse amplitude and the recovery time t_{c} are determined based on a post-pulse relaxation time tᵣ. Then the relaxation time tᵣ is determined based on the pulse amplitude (that is, the discharge current) and the recovery time t_{c}. This process is repeated until the load curve obtained through calculation is consistent with the predicted load curve, that is, an optimal result is obtained. After the above steps are performed on the plurality of cells, an actually required discharge pulse of the battery at the next moment is determined according to step (c) based on principles of Min{t_{ci}}, Max{tᵣᵢ}, and Min{Iᵢ}.

When the battery has a plurality of serially connected cells, due to inevitable inconsistency among the cells, depths of discharge of the cells are inconsistent during a discharge, thereby causing an over-discharge of some cells under a condition. A long-term uncontrolled over-discharge of the cell can easily accelerate aging of the cell and even lead to thermal runaway. This case is more obvious when the battery is quickly discharged. In an existing battery management system (such as passive or active management of lithium batteries), due to a limited balance capability between cells, balance of the cell during a discharge is not supported. Imbalance of the cell causes some cells to be over-discharged, or a discharge capacity of the battery drops significantly. In order to ensure a maximum value of a quantity of discharge electricity in a state of health of each cell, it is necessary to balance the cell when the battery is discharged. A most appropriate value is re-determined as a next discharge pulse according to real-time data of all the cells of the battery at each moment. In this way, this can reduce a requirement for consistency among the cells in the battery structure with the plurality of serially connected cells, resolve a problem of charge balance of the battery, and make full use of a battery capacity.

Before the discharge pulse of each cell at the next moment is determined, if at least one of a plurality of cells is close to a discharge cut-off state, the cell close to a discharge cut-off state is charged by using another cell. Then the discharge pulse of each cell at the next moment is determined based on the real-time data of the battery, in comparison with a curve of the recovery time t_{c} and the relaxation time tᵣ of each cell varying with the discharge current of the cell, the temperature, the state of health SOH of the battery, the state of charge SOC, and the depth of discharge DOD of the battery, and with reference to the predicted load curve.

The manner of charging the cell close to a discharge cut-off state includes: performing charging by using one of other cells, such as a cell with a largest quantity of remaining electricity, so that a quantity of electricity of the fully charged cell is slightly different from a quantity of electricity of another cell; or performing charging by using a plurality of the other cells, such as a cell having a largest quantity of electricity and a cell having a second largest quantity of electricity; or performing charging by using all the other cells, for example, performing charging evenly and equally. In the charge process, both overcharging and undercharging should not be performed to ensure that quantities of electricity of cells are almost the same each time charging is performed, in other words, ensure consistency among the cells.

The battery formed by the plurality of cells that are successively connected in parallel shown in FIG. 7b is used as an example. The real-time data of the battery includes temperature 1, a discharge current 1, a discharge voltage 1, a depth 1 of discharge, an SOC 1, and an SOH 1 of a cell 1; temperature 2, a discharge current 2, a discharge voltage 2, a depth of discharge 2, an SOC 2, and an SOH 2 of a cell 2; temperature 3, a discharge current 3, a discharge voltage 3, a depth 3 of discharge, an SOC 3, and an SOH 3 of a cell 3 . . . ; temperature n, a discharge current n, a discharge voltage n, a depth n of discharge, an SOC n, and an SOH n of a cell n. Each cell includes parameters of a discharge current I, a recovery time t_{c}, and a relaxation time tᵣ (referring to FIG. 7b). First, by predicting the load curve, an amplitude and a width of the discharge current pulse are measured, and then the pulse amplitude and the recovery time t_{c} are determined based on a post-pulse relaxation time tᵣ. Then the relaxation time tᵣ is determined based on the pulse amplitude (that is, the discharge current) and the recovery time t_{c}. This process is repeated until the load curve obtained through calculation is consistent with the predicted load curve, that is, an optimal result is obtained. After the above steps are performed the a plurality of cells, an actually required battery discharge pulse at the next moment is determined according to step (c) based on principles of Min{t_{ci}}, Max{tᵣᵢ}, and Min{Iᵢ}.

Due to inconsistency among cells, currents passing through the cells are different at an equal voltage. In order to ensure health of each cell and determine the parameters of the discharge pulse, Min{Iᵢ}, Min{t_{ci}}, and max{tᵣᵢ} are used to determine the discharge pulse of the system. When smart pulse discharges are performed, a problem of a bias current when each cell is discharged can be effectively suppressed.

The battery formed by plurality of cells that are connected serially and in parallel shown in FIG. 7c and FIG. 7d is used as an example. The real-time data of the battery includes temperature 1, a discharge current 1, a discharge voltage 1, a depth 1 of discharge, an SOC 1, and an SOH 1 of a cell 1; temperature 2, a discharge current 2, a discharge voltage 2, a depth of discharge 2, an SOC 2, and an SOH 2 of a cell 2; temperature 3, a discharge current 3, a discharge voltage 3, a depth 3 of discharge, an SOC 3, and an SOH 3 of a cell 3 . . . , temperature n, a discharge current n, a discharge voltage n, a depth n of discharge, an SOC n, and an SOH n of a cell n. Each cell includes parameters of a discharge current I, a recovery time t_{c}, and a relaxation time tᵣ (as shown in FIG. 7c and FIG. 7d). First, by predicting the load curve, an amplitude and a width of the discharge current pulse are measured, and then the pulse amplitude and the recovery time t_{c} are determined based on the post-pulse relaxation time tᵣ. Then the relaxation time tᵣ is determined based on the pulse amplitude (that is, the discharge current) and the recovery time t_{c}. This process is repeated until the load curve obtained through calculation is consistent with the predicted load curve, that is, an optimal result is obtained. After the above steps are performed on a plurality of cells, an actually required discharge pulse of the battery at the next moment is determined according to step (c) based on principles of Min{t_{ci}}, Max {tᵣᵢ}, and Min{Iᵢ}.

For serially connected cells, due to extension of an aging characteristic of the serially connected cells during normal operation and a difference between self-discharge rates of batteries, battery charges are not balanced. For cells connected in parallel, due to inconsistency among the cells, currents passing through the cells are different at an equal voltage, and a bias current is formed. For this reason, in consideration of a difference of each cell and healthy use of the cell, the entire battery is discharged by using a smallest recovery time value among all the cells, recovery is performed by using a maximum relaxation time value among all the cells, and a minimum discharge current is used. A most appropriate value is re-determined as a next discharge pulse according to real-time data of all the cells of the battery at each moment. In this way, this can reduce a requirement for consistency among the cells in the battery structure with the plurality of cells, resolve a problem of charge balance of the battery, make full use of a battery capacity, and effectively suppress a bias current when each cell is discharged.

For serially connected cells, before the discharge pulse of each cell at the next moment is determined, if at least one of a plurality of cells is close to a discharge cut-off state, the cell close to a discharge cut-off state is charged by using another cell. Then the discharge pulse of each cell at the next moment is determined based on the real-time data of the battery, in comparison with a curve of the recovery time t_{c} and the relaxation time tᵣ of each cell varying with the discharge current of the cell, the temperature, the state of health SOH of the battery, the state of charge SOC, and the depth of discharge DOD of the battery, and with reference to the predicted load curve.

The manner of charging the cell close to a discharge cut-off state includes: performing charging by using one of other cells, such as a cell with a largest quantity of remaining electricity, so that a quantity of electricity of the fully charged cell is slightly different from a quantity of electricity of another cell; or performing charging by using a plurality of the other cells, such as a cell having a largest quantity of electricity and a cell having a second largest quantity of electricity; or performing charging by using all the other cells, for example, performing charging evenly and equally. In the charge process, both overcharging and undercharging should not be performed to ensure that quantities of electricity of cells are almost the same each time charging is performed, in other words, ensure consistency among the cells.

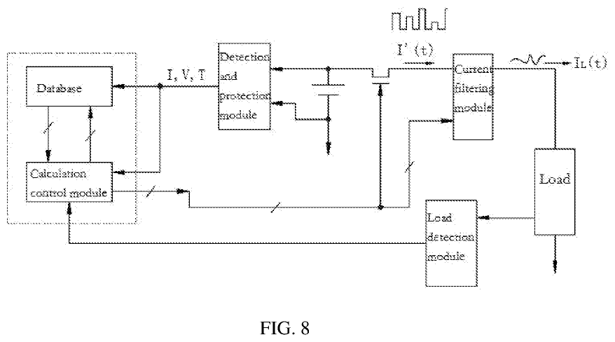

FIG. 8 shows a discharge system. The system includes a battery module, a detection and protection module, a load, a load detection module, a current filtering module, a database, and a calculation control module. The database stores change information of a recovery time t_{c} and a relaxation time tᵣ of a battery. The recovery time t_{c} is a largest continuous discharge time of a cell, and distortion of an electrode structure caused within the time can be eliminated in the subsequent relaxation time. The recovery time t_{c} varies with a discharge current of the cell, temperature, a state of health SOH of the battery, a state of charge SOC, and a depth of discharge DOD of the battery. The relaxation time tᵣ is a time required for recovering a distorted electrode structure to an original state, and the relaxation time tᵣ varies with the discharge current of the cell, the temperature, the state of health SOH of the battery, the state of charge SOC, and the depth of discharge DOD of the battery. The detection and protection module is configured to detect the battery module in real time, to obtain real-time data of the battery. The real-time data of the battery includes voltage, current, and temperature data of the battery. The load detection module is configured to detect the load in real time, to obtain real-time data of the load. The real-time data of the load includes voltage, current, and temperature data of the load. The calculation control module calculates a discharge pulse at a next moment based on the real-time data of the load, the real-time data of the battery, and the change information of the recovery time t_{c} and the relaxation time tᵣ, and the discharge pulse includes the discharge current, the recovery time t_{c}, and the relaxation time tᵣ of the cell. The battery module performs discharging based on a control signal of the calculation control module, and forms, by the discharge pulse by using the current filtering module, a current waveform required by the load, until the load is fully charged or the cell is discharged to a cut-off state.

The system can track aging of the battery and a change in (t_{c}, tᵣ) in a full life cycle, and at the same time, can take a protective measure in an extreme case, to ensure that the battery is not over-discharged.

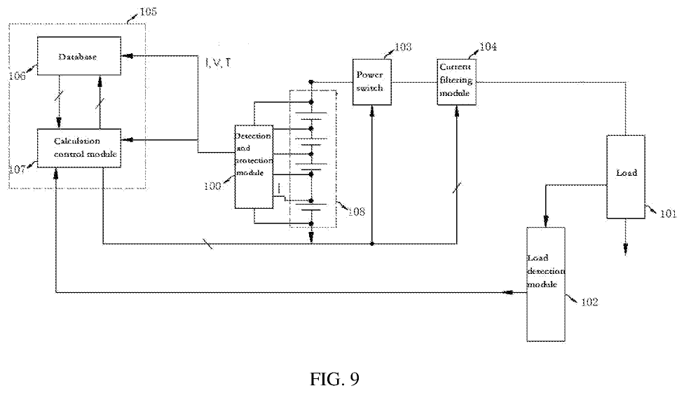

The battery module is a battery with a single cell, and the battery module may also be a battery with a plurality of cells (referring to FIG. 9). When the battery is the battery with a plurality of cells, the battery structure may be formed by the plurality of serially connected cells (referring to FIG. 9), or formed by the plurality of cells connected in parallel, or formed by the plurality of cells connected serially and in parallel.

The detection and protection module includes a detection circuit and a protection circuit. The detection circuit may use a detection circuit that can detect a voltage, a current, and temperature of the battery. The protection circuit may use a commonly used circuit for a battery overcurrent, overheating, and overvoltage protection. If protection is required, a protection function is enabled immediately.

The database includes an initial database, a status database, and a historical database. The database stores a discharge curve, a load curve, an SOH, an SOC, internal resistance, a recovery time t_{c}, a relaxation time tᵣ, a depth of discharge DOD, and change information of the recovery time t_{c} and the relaxation time tᵣ varying with the discharge current, the temperature, the SOC, the SOH, and the depth of discharge. At an initial stage, initial data in the initial database is provided by a battery manufacturer, such as the load curve, the discharge curve, the SOH, the SOC, and the internal resistance, and is determined based on provided initial information, such as the recovery time t_{c}, the relaxation time tᵣ, and the change information of the recovery time t_{c} and the relaxation time tᵣ varying with the discharge current, the temperature, the SOC, the SOH, and the depth of discharge. In a use phase of the discharge system, the status database stores the above information updated in real time. The historical database stores the foregoing battery data in different phases. The status database outputs status data to the historical database. The historical database feeds back information to the status database, information in the database is corrected in each discharge cycle, such as the recovery time t_{c}, the relaxation time tᵣ, and the change information of the recovery time t_{c} and the relaxation time tᵣ varying with the discharge current, the temperature, the SOC, the SOH, and the depth of discharge, so as to ensure that the battery is discharged healthily and efficiently.

Specifically, for a battery formed by a single cell, the calculation control module includes a load curve determining unit and a cell discharge pulse calculation unit. The load curve determining unit is configured to determine a predicted load curve based on the real-time data of the load. The cell discharge pulse calculation unit is configured to determine a discharge pulse of each cell at a next moment based on the real-time data of the battery, in comparison with a curve of the recovery time t_{c} and the relaxation time tᵣ of each cell varying with the discharge current of the cell, the temperature, the state of health SOH of the battery, the state of charge SOC, and the depth of discharge DOD of the battery, and with reference to the predicted load curve.

Specifically, for a battery formed by a plurality of cells, the calculation control module includes a load curve determining unit, a cell discharge pulse calculation unit, and a battery discharge pulse calculation unit. The load curve determining unit is configured to determine a predicted load curve based on the real-time data of the load. The cell discharge pulse calculation unit is configured to determine the discharge pulse of each cell at the next moment based on the real-time data of the battery, in comparison with the curve of the recovery time t_{c} and the relaxation time tᵣ of each cell varying with the discharge current of the cell, the temperature, the state of health SOH of the battery, the state of charge SOC, and the depth of discharge DOD of the battery, and with reference to the predicted load curve. The battery discharge pulse calculation unit is configured to constitute a discharge pulse of the battery at the next moment by using a minimum value of discharge currents, a minimum value of the recovery time, and a maximum value of the relaxation time of all cells.

The calculation control module further includes: a filtering calculation unit, configured to perform filtering calculation on the discharge pulse of the battery. When a load curve obtained through calculation is consistent with the predicted load curve, the calculation control module sends a control instruction including the discharge pulse of the battery to the battery module; otherwise, the load curve determining unit, the cell discharge pulse calculation unit, and the battery discharge pulse calculation unit calculate the discharge pulse of the battery again.

FIG. 9 shows a discharge system of a battery with a plurality of serially connected cells. Due to inevitable inconsistency among the cells, depths of discharge of the cells are inconsistent during a discharge, thereby causing an over-discharge of some cells under a condition. A long-term uncontrolled over-discharge of the cell can easily accelerate aging of the cell and even lead to thermal runaway. This case is more obvious when the battery is quickly discharged. However, the discharge system can resolve the foregoing problem by monitoring and managing the battery in a full life cycle. The system includes a battery module, a detection and protection module, a load, a load detection module, a current filtering module, a database, a calculation control module, a battery energy management module, and a switch module.

The detection and protection module 100 is configured to: detect a current, a voltage, and temperature of each cell of the battery in real time, protect the battery in an extreme case, perform simple balance between cells of the battery, and perform energy management between the cells of the battery. The load monitoring module 102 is configured to monitor the load 101. The switch module may be a power switch 103, and is configured to generate a pulse discharge current. The current filtering module 104 is configured to filter a pulse current to generate a current waveform required by the load. The database 106 includes a local area database and a cloud database.

The database 106 and the calculation control module 107 calculate and generate a control signal after receiving battery detection and load detection information, and control the power switch and the current filtering module. First an initial battery parameter, algorithms of an SOC, an SOH, internal resistance, and the like of the battery, and a curve of a pulse amplitude Iᵢ, t_{ci}, tᵣᵢ of a cell of the battery varying with temperature, the SOC, and the SOH is entered into the database. Data tested by the detection and protection module 100 is entered into the database in real time. In addition, a curve of t_{ci} and a curve of tᵣᵢ of each cell at that moment are corrected through calculation (the calculation control module 107). A minimum min{t_{ci}}, a maximum max{tᵣᵢ}, and minimum min{Iᵢ} of the battery system are calculated, a discharge current pulse is generated, and a load current curve is generated by using the filtering module. In addition, the calculation module grasps imbalance information of each cell by calculating a DOD of each cell. The detection and protection module 100 balances the cells within a pulse interval min{tri}, so that DODs of cells are close. The detection and protection module 100 continuously detects the cells and behavior in the battery system in real time, and generates a subsequent pulse sequence, until the load is received or the battery is discharged to a cut-off state.

The battery energy management module (not shown in the figure) and the switch module are disposed between the battery module and the current filtering module. The calculation control module further includes a charge control unit, configured to: when the battery energy management module detects that at least one of a plurality of cells is close to a discharge cut-off state, control the switch module to cut off a discharge path and control another cell to charge the cell close to a discharge cut-off state; and after the charging is completed, then control the switch module to turn on the discharge path, and trigger the load curve determining unit, the cell discharge pulse calculation unit, and the battery discharge pulse calculation unit to work.

A person skilled in the art should understand that the embodiments of the present invention described above and shown in the accompanying drawings are merely examples and do not limit the present invention. The objective of the present invention has been completely and effectively achieved. The function and structural principle of the present invention have been shown and described in the embodiments, and the implementations of the present invention can be varied or modified without departing from the principle.

1. (canceled)

2. (canceled)

3. (canceled)

4. (canceled)

5. (canceled)

6. (canceled)

7. A method for discharging a battery in a full life cycle, being applicable to a battery formed by serially connecting a plurality of cells, or a battery formed by connecting a plurality of cells in parallel, or a battery formed by connecting a plurality of cells serially and in parallel, and the method comprising:
monitoring real-time data of the plurality of cells of a discharged battery and real-time data of a load based on a discharge pulse of the battery at a current moment;
calculating a discharge pulse of the battery at a next moment based on the real-time data of the load, the real-time data of the plurality of the cells of the battery, and changing information of a recovery time t_{c} and a relaxation time tᵣ; wherein the step of calculating a discharge pulse of the battery at the next moment based on the real-time data of the load, the real-time data of the plurality of the cells of the battery, and changing information of a recovery time t_{c} and a relaxation time tᵣ comprises:
obtaining a predicted load curve based on the real-time data of the load;
determining a discharge pulse of a cell of the plurality of cells at the next moment, further including:
applying the real-time data of the cell of the plurality cells of the battery to a curve of the recovery time t_{c} of the cell varying with the discharge current of the cell, the temperature, the state of health SOH of the battery, the state of charge SOC, and the depth of discharge DOD of the battery, and applying the real-time data of the cell of the plurality of the cells of the battery to a curve of the relaxation time tᵣ of the cell varying with the discharge current of the cell, the temperature, the state of health SOH of the battery, the state of charge SOC, and the depth of discharge DOD of the battery, to determine the discharge current of the cell, the recovery time t_{c}, and the relaxation time tᵣ;
obtaining a calculated load curve based on the determined discharge current of the cell, the recovery time t_{c} and the relaxation time tᵣ, and comparing the calculated load curve with the predicted load curve, and
repeating said applying, obtaining and comparing processes until the calculated load curve is consistent with the predicted curve;
repeating said step of determining the discharge pulse of the cell until discharge pulses of the plurality of cells have been determined;
determining a discharge pulse of the battery at the next moment by using a minimum value of discharge currents, a minimum value of the recovery time, and a maximum value of the relaxation time of the plurality of cells;
forming, by the discharge pulse by controlling current filtering, a current waveform at the next moment required by the load; and
performing discharging by using the calculated discharge pulse, charging the load by using the current waveform obtained after calculation, and performing a discharge process until the load is fully charged or the battery is discharged to a cut-off state, wherein
the real-time data of the plurality of the cells of the battery comprises voltage, current, and temperature data of the battery, and the real-time data of the load comprises voltage, current, and temperature data of the load;
the recovery time is a largest continuous discharge time of the battery, and distortion of an electrode structure caused within the time can be eliminated in the subsequent relaxation time; and the recovery time t_{c} varies with a discharge current of the cell, temperature, a state of health SOH of the battery, a state of charge SOC, and a depth of discharge DOD of the battery;
the relaxation time tᵣ is a time required for recovering a distorted electrode structure to an original state, and the relaxation time tᵣ varies with the discharge current of the cell, the temperature, the state of health SOH of the battery, the state of charge SOC, and the depth of discharge DOD of the battery; and
the discharge pulse comprises the discharge current of the cell, the recovery time t_{c}, and the relaxation time tᵣ.

8. (canceled)

9. The method for discharging the battery in a full life cycle according to claim 7, wherein when the battery comprises serially connected cells, the step of calculating a discharge pulse at a next moment based on the real-time data of the load, the real-time data of the battery, and changing information of a recovery time t_{c} and a relaxation time tr further comprises:
before the discharge pulse of the cell at the next moment is determined, if at least one of a plurality of cells is close to cut-off state, charging the cell close to the cut-off state by using another cell; and
then determining the discharge pulse of the cell at the next moment, further including:
comparing the real-time data of the battery with a curve of the recovery time t_{c} of the cell varying with the discharge current of the cell, the temperature, the state of health SOH of the battery, the state of charge SOC, and the depth of discharge DOD of the battery, and comparing the real-time data of the battery with a curve of the relaxation time tᵣ of the each cell varying with the discharge current of the cell, the temperature, the state of health SOH of the battery, the state of charge SOC, and the depth of discharge DOD of the battery, to determine the discharge current of the cell, the recovery time t_{c}, and the relaxation time tᵣ;
comparing a calculated load curve which is determined based on the determined discharge current of the cell, the recovery time tc, and the relaxation time tr, with the predicted load curve, and
repeating said comparison process until the calculated load curve is consistent with the predicted curve;
repeating said step of determining the discharge pulse of the cell until the discharge pulse of the plurality of cells have been determined.

10. The method for discharging the battery in a full life cycle according to claim 7, wherein the step of forming, by the discharge pulse by controlling current filtering, a current waveform at the next moment required by the load comprises:
performing filtering calculation, performing filtering processing when a load curve obtained through calculation is consistent with the predicted load curve, and filtering the discharge pulse to form the current waveform.

11. (canceled)

12. The method for discharging the battery in a full life cycle according to claim 7, wherein the method further comprises: correcting a curve of the cell in real time based on the real-time data of the battery, the state of health SOH of the battery, the state of charge SOC, and the depth of discharge DOD of the battery.

13. The method for discharging the battery in a full life cycle according to claim 7, wherein the method is applicable to a discharge of a chemical battery.

14. A system for discharging a battery in a full life cycle, being applicable to a battery formed by serially connecting a plurality of cells, or a battery formed by connecting a plurality of cells in parallel, or a battery formed by connecting a plurality of cells serially and in parallel, and the system comprising a battery module, a detection and protection module, a load, a load detection module, a current filtering module, a database, and a calculation control module;
the database stores changing information of a recovery time t_{c} and a relaxation time tᵣ of the battery; the detection and protection module is configured to detect the battery module in real time, to obtain real-time data of the plurality of cells of the battery; the load detection module is configured to detect the load in real time, to obtain real-time data of the load; the calculation control module calculates a discharge pulse of the battery at a next moment based on the real-time data of the load, the real-time data of the plurality of cells of the battery, and the changing information of the recovery time t_{c} and the relaxation time tᵣ of the battery; the battery module performs discharging based on a control signal of the calculation control module, and forms, by the discharge pulse by using the current filtering module, a current waveform required by the load, until the load is fully charged or a cell is discharged to a cut-off state;
wherein the calculation control module comprises:
a load curve determining unit, configured to obtain a predicted load curve based on the real-time data of the load;
a cell discharge pulse calculation unit, configured to determine a discharge pulse of a cell of the plurality of cells at a next moment, further including:
configured to apply the real-time data of the battery to a curve of the recovery time t_{c} of the cell varying with the discharge current of the cell, the temperature, the state of health SOH of the battery, the state of charge SOC, and the depth of discharge DOD of the battery, and apply the real-time data of the battery to a curve of the relaxation time tᵣ of the cell varying with the discharge current of the cell, the temperature, the state of health SOH of the battery, the state of charge SOC, and the depth of discharge DOD of the battery, to determine the discharge current of the cell, the recovery time t_{c} and the relaxation time tᵣ; and
configured to obtain a calculated load curve based on the determined discharge current of the cell, the recovery time t_{c}, and the relaxation time tᵣ, and compare the calculated load curve with the predicted load curve, and
configured to repeat said apply, obtain and compare until the calculated load curve is consistent with the predicted curve;
a battery discharge pulse calculation unit, configured to determine a discharge pulse of the battery at a next moment by using a minimum value of discharge currents, a minimum value of the recovery time, and a maximum value of the relaxation time of the plurality of cells;
the real-time data of the battery comprises voltage, current, and temperature data of the battery, and the real-time data of the load comprises voltage, current, and temperature data of the load;
the recovery time t_{c} is a largest continuous discharge time of the battery, and distortion of an electrode structure caused within the time can be eliminated in the subsequent relaxation time;
and the recovery time t_{c} varies with a discharge current of the cell, temperature, a state of health SOH of the battery, a state of charge SOC, and a depth of discharge DOD of the battery;
the relaxation time tᵣ is a time required for recovering a distorted electrode structure to an original state, and the relaxation time tᵣ varies with the discharge current of the cell, the temperature, the state of health SOH of the battery, the state of charge SOC, and the depth of discharge DOD of the battery; and
the discharge pulse comprises the discharge current of the cell, the recovery time t_{c}, and the relaxation time tᵣ.

15. (canceled)

16. The system for discharging a battery in a full life cycle according to claim 14, wherein the calculation control module further comprises: a filtering calculation unit, configured to perform filtering calculation on the discharge pulse of the battery; when a load curve obtained through calculation is consistent with the predicted load curve, the calculation control module sends a control instruction comprising the discharge pulse of the battery to the battery module; otherwise, the load curve determining unit, the cell discharge pulse calculation unit, and the battery discharge pulse calculation unit calculate the discharge pulse of the battery again.

17. The system for discharging the battery in a full life cycle according to claim 14, further comprising a battery energy management module and a switch module that are disposed between the battery module and the current filtering module; the calculation control module further comprises a charge control unit, configured to: when the battery energy management module detects that at least one of a plurality of cells is close to the cut-off state, control the switch module to cut off a discharge path and control another cell to charge the cell close to the cut-off state; and after the charging is completed, then control the switch module to turn on the discharge path, and trigger the load curve determining unit, the cell discharge pulse calculation unit, and the battery discharge pulse calculation unit to work.
